(19) United States
(12) Patent Application Publication
(10) Pub. No.: US 2009/0279246 A1
(43) Pub. Date: Nov. 12, 2009

(54) Global Heat Sink Carrier for Electronics Components

(75) Inventors: Quoc Hoai Nguyen, Round Rock, TX (US); Sanjoy Kumar Saha, Round Rock, TX (US)

Correspondence Address: BAKER BOTTS, LLP, 910 LOUISIANA, HOUSTON, TX, 77002-4995, US

(73) Assignee: DELL PRODUCTS L.P., Round Rock, TX (US)

(21) Appl. No.: 12/119,047

(22) Filed: May 12, 2008

(51) Int. Cl. G06F 1/16; H05K 7/20; G06F 1/20; H05K 7/00

(52) U.S. Cl. 361/679.34; 361/679.54

(57) ABSTRACT

A system for mounting an electronic component associated with an information handling system is disclosed. The system may comprise a carrier configured to carry an electronic component and a caddy configured to mount the carrier and the electronic component to a structure of the information handling system. The carrier may include a mass providing a heat sink to the electronic component and one or more fins for transferring heat from the mass. The carrier and the caddy may operate in conjunction as a damper to attenuate vibration.

### TECHNICAL FIELD

The present disclosure relates in general to electronics components and more particularly to an electronic component carrier with an integrated heat sink for use in an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

FIG. 1 depicts selected elements of an example prior art information handling system 1. Information handling system 1 includes a host 10, which may include processing resources (e.g., one or more central processing units (CPUs)) and storage resources that are accessible to the processing resources in a housing 12. Storage resources may include volatile storage or memory and/or persistent storage, e.g., disk storage, flash memory or other type of erasable read only memory (ROM), and the like. Information handling system 1 may also include various other peripheral or I/O devices known in the field of data processing system design, e.g., mouse 14, display 20, and keyboard 30 shown in FIG. 1. Housing 12 may include any chassis, cabinet, tower, box, and/or enclosure appropriate for housing information handling system 1.

FIG. 2 depicts selected elements of a prior art hard disk drive 40. Hard disk drive 40 (also referred to as hard drive, hard disk, or fixed disk drive) is a persistent storage device configured to store digitally encoded data. Hard disk drive 40 may include one or more platters 42, a spindle 43, an actuator arm 44, one or more read/write heads 45, a data port 46, and a power connector 47. Hard disk drive 40 may be configured for use in a wide variety of information handling systems (e.g., server, desktop computer, laptop computer, digital video cameras, a PDA, a cellphone, a digital audio player, or a video game console).

Hard disk drive 40 may record data by magnetizing portions of platter 42. The orientation of each bit of material of platter 42 represents a bit of data (e.g., either 0 or 1). Typically, platter 42 is made of a non-magnetic material coated with a thin layer of magnetic material (e.g., iron oxide or cobalt alloys). Platter 42 is mounted on spindle 43 so it may be rotated or spun at high speed. Actuator arm 44 is mounted adjacent platter 42 so that read/write head 45 can be moved across the surface of platter 42. The speed of actuator arm 44 may affect the seek speed of hard disk drive 40. Read/write head 45 is typically configured to detect and/or modify the magnetic orientation of the magnetic material of platter 42.

Platter 42 is typically rotated by a motor or drive connected to spindle 43. Heat and/or noise generated by the components driving spindle 43 may be significant to the overall performance of information handling system 1. For example, audible noise may be problematic in audio recording and/or so-called “quiet computers.” Low noise hard disk drives may include fluid bearings, reduced rotational speeds, and reduced seek speeds which may result in increased cost and/or reduced performance characteristics. As another example, heat generated by the operation of hard disk drive 40 may raise the operating temperature of hard disk drive 40 and/or other components of information handling system 1.

Data port 46 may be any type of data connector. Hard disk drive 40 typically includes one of several standard data bus types (e.g., parallel ATA (PATA), serial ATA (SATA), SCSI, Serial Attached SCSI, and Fibre Channel) Power connector 47 may be any type of power connector suited for use with a power supply associated with information handling system 1.

Hard disk drive 40 may fit within a designated “form factor” known in the art. For example, an “8-inch” drive fits within a form factor of approximately 9.5 inches×4.624 inches×14.25 inches. As another example, a “3.5-inch” drive fits within a form factor of approximately 4 inches×1 inch×5.75 inches. 3.5-inch drives are commonly used in desktop computers. As another example, a “2.5-inch” drive fits within a form factor of approximately 2.75 inches×0.374 inches×3.945 inches. 2.5-inch drives are widely used in laptop and notebook computers.

### SUMMARY

In accordance with one embodiment of the present disclosure, a system for mounting an electronic component associated with an information handling system is disclosed. The system may comprise a carrier configured to carry an electronic component and a caddy configured to mount the carrier and the electronic component to a structure of the information handling system. The carrier may include a mass providing a heat sink to the electronic component and one or more fins for transferring heat from the mass. The carrier and the caddy may operate in conjunction as a damper to attenuate vibration.

In accordance with a further embodiment of the present disclosure, a device associated with an information handling system is disclosed. The device may include a hard disk drive including a rotating component, a carrier configured to carry the hard disk drive, and a caddy configured to mount the carrier and the hard disk drive to a structure of the information handling system. The carrier may include a mass providing a heat sink to the hard disk drive and one or more fins for transferring heat from the mass. The carrier and the caddy may operate in conjunction as a damper to attenuate vibration associated with operation of the rotating component of the hard disk drive.

In accordance with another embodiment of the present disclosure, an information handling system is disclosed. The information handling system may include a processor, a memory communicatively coupled to the processor, a frame for mounting the processor and the memory, a carrier configured to carry an electronic component, and a caddy configured to mount the carrier and the electronic component to the frame. The carrier may include a mass providing a heat sink to the electronic component and one or more fins for transferring heat from the mass. The carrier and the caddy may operate in conjunction as a damper to attenuate vibration associated with operation of the electronic component.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an example prior art information handling system;

FIG. 2 illustrates an example prior art hard disk drive;

FIG. 3 illustrates an embodiment of a system for mounting an electronic component associated with an information handling system in accordance with the present disclosure;

FIG. 4a illustrates an embodiment of a carrier for mounting an electronic component associated with an information handling system in accordance with the present disclosure;

FIG. 4b illustrates the reverse side of the carrier depicted in FIG. 4b; and

FIG. 5 illustrates an embodiment of a caddy for mounting the electronic component carrier shown in FIGS. 4a and 4b, in accordance with the present disclosure.

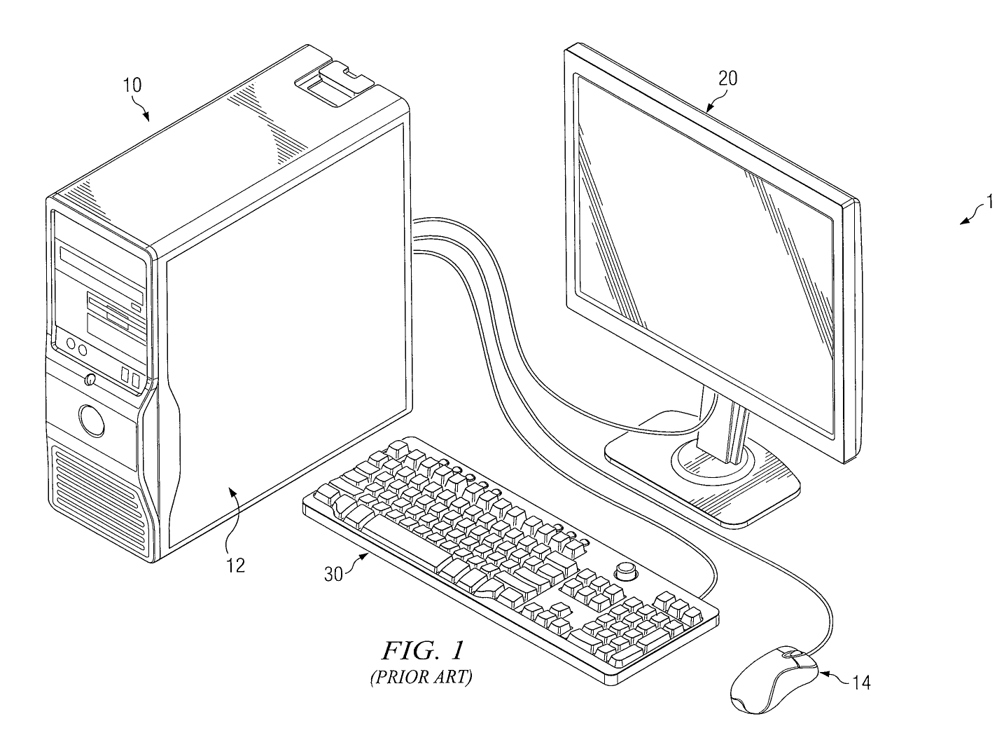

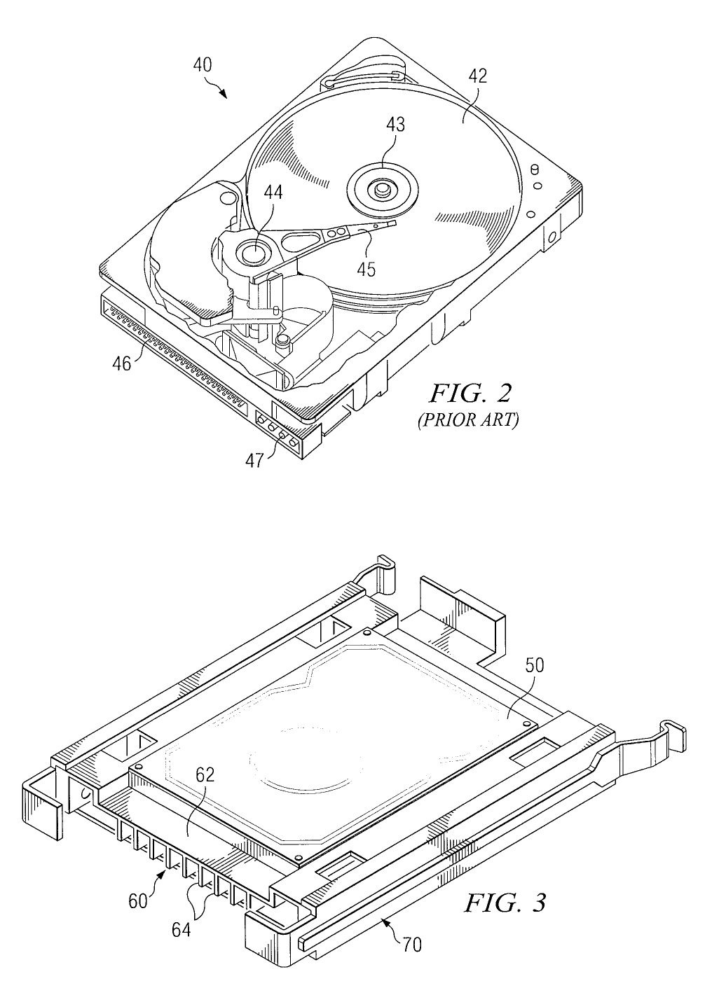

### DETAILED DESCRIPTION

Preferred embodiments and their advantages are best understood by reference to FIGS. 3-5, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components or the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

The development of electronic components (e.g., hard disk drives) for use with information handling systems has resulted in increased performance in terms of data read/write speed, data capacity, and other metrics. In large part, these increases are supported by increased rotational speed of certain components (e.g., the platter of a hard disk drive). As a result of these increased speeds, the operation of such electronic components may generate increased heat loads. At the same time, increased speeds may generate increased vibration and noise in comparison to slower speeds.

In addition, improved electronic components may produce increased cooling loads in comparison to slower electronic components. Known methods for cooling electronic components may include passive cooling and/or active cooling with forced convection, for example. Active cooling may produce additional power consumption and/or noise generation in comparison to passive cooling solutions.

FIG. 3 illustrates one embodiment of a system for mounting an electronic component 50 (e.g., a hard disk drive) associated with an information handling system in accordance with the present disclosure. The system may include a carrier 60 and a caddy 70. The carrier and the caddy may operate in conjunction as a damper to attenuate vibration generated by the operation of electronic component 50.

Electronic component 50 may include any device or component of an information handling system. For example, electronic component 50 may include processing resources (e.g., one or more central processing units), storage units (e.g., a hard disk drive), and/or any device configured to control data, to process data, to convert electric power (e.g., sensors, transducers, and actuators), and/or to distribute electric power.

Carrier 60 may be any device or component of the system configured to carry electronic component 50. For example, carrier 60 may be formed with a recess sized to be compatible with the exterior dimensions of electronic component 50. Carrier 60 may be configured to increase the thermal mass of associated electronic component 50. For example, in embodiments such as that shown in FIG. 3, carrier 60 may include a mass 62 and one or more fins 64.

Mass 62 may be formed from any appropriate material or component configured to increase heat transfer away from electronic component 50. For example, mass 62 may serve to increase the heat dissipation associated with electronic component 50. Mass 62 may include material with relatively high thermal conductivity (e.g., a metal block or aluminum and/or copper alloy). Mass 62 may be fabricated and/or shaped in any manner to facilitate heat transfer between electronic component 50 and mass 62 and/or to facilitate mounting mass 62 to associated structure of carrier 60.

Fins 64 may include any component or feature of carrier 60 configured to increase heat transfer from mass 62 to the environment. Fins 64 may serve to increase the surface area of carrier 60 and/or mass 62 and, therefore, increase the rate of heat transfer through convection, conduction, and/or radiation between mass 62 and the environment. Although the embodiment shown in FIG. 3 includes long, thin fins, fins 64 may include any physical features or characteristics that increase the surface area-to-volume ratio of carrier 60 and/or mass 62. Like mass 62, fins 64 may also be made of any material with relatively high thermal conductivity (e.g., aluminum and/or copper alloy).

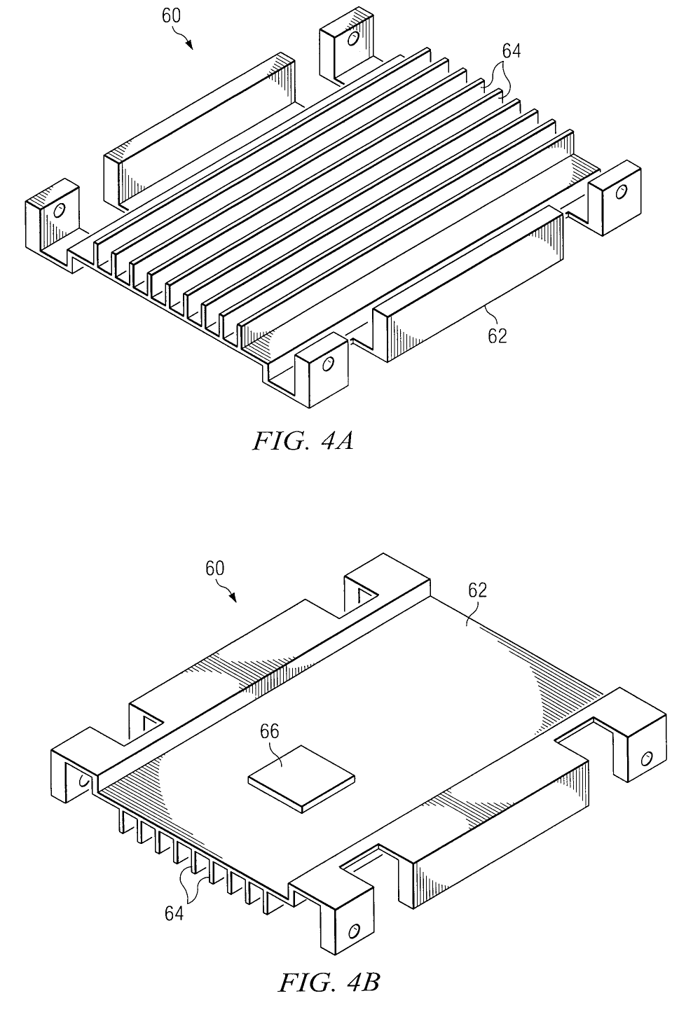

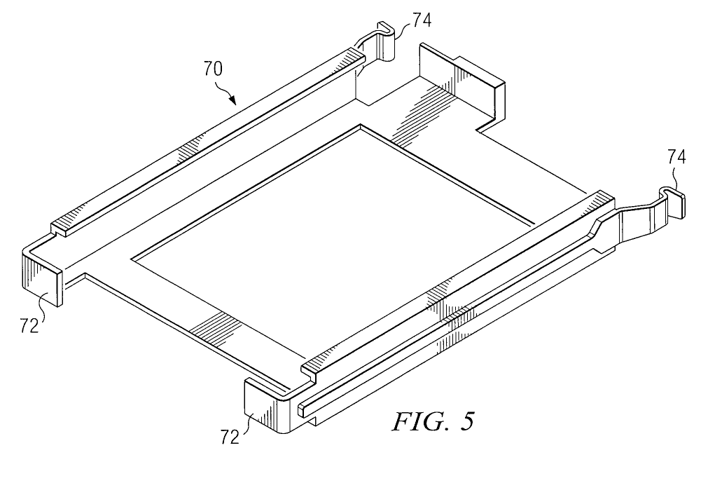

In embodiments such as that shown in FIG. 3, carrier 60, mass 62, and/or fins 64 may provide sufficient thermal dissipation for the operation of electronic component 50 to eliminate the need for active cooling components (e.g., fans, liquid coolant, etc.). Laboratory testing of one embodiment of carrier 60 resulted in the reduction of the temperature of a hard disk drive by more than seven (7) degrees Celsius with passive cooling, as shown in graph 80 of FIG. 4.

In some applications, reduction in temperature of more than seven (7) degrees Celsius may reduce the need for active cooling of an associated information handling system. In one example information handling system, a similar reduction in the operating temperature of a hard disk drive may result in a 28% noise reduction in the operation of a cooling system associated with the information handling system. In other embodiments, carrier 60 may be configured to mount two or more electronic components (e.g., multiple hard disk drives). As another example, carrier 60 may be configured for use with liquid cooling systems to increase the cooling capacity of an associated information handling system.

FIGS. 5a and 5b show examples of carrier 60 in greater detail. As shown in FIG. 5b, carrier 60 may include a gap pad 66. Gap pad 66 may include a thermal interface between electronic component 50 and carrier 60.

Gap pad 66 may include any thermal interface material providing conformability, high thermal conductivity, and/or easy installation or application. Embodiments including gap pad 66 may eliminate air gaps between electronic component 50 and carrier 60 whether due to uneven surface topography and/or rough surface textures. In some embodiments, gap pad 66 may be disposed to be directly beneath rotating elements of electronic component 50 (e.g., a platter of a hard disk drive).

FIG. 6 depicts selected components of one embodiment of a caddy 70 in accordance with teachings of the present disclosure. Caddy 70 may be any device or component of the system configured to mount electronic component 50 and carrier 60 to a structure of the information handling system. For example, caddy 70 may be configured to mount electronic component 50 and carrier 60 to the case or housing of a desktop computer, a laptop computer, and/or any other information handling system.

Caddy 70 may be configured to isolate vibrations resulting from the operation of electronic component 50. As one example, caddy 70 may include a cantilever bracket configured to attach carrier 60 to the case or housing of an information handling system. In such embodiments, carrier 60 may include flexible components or flexible material configured to provide a spring-like mounting for carrier 60.

In accordance with teachings of the present disclosure, carrier 60 and caddy 70 may operate in conjunction as a damper to attenuate vibration. For example, the selection of the weight of mass 62 may provide damping (e.g., for low frequency vibration and/or for high frequency vibration). When selected in conjunction with isolation mounting with caddy 70, noise related to the operation of electronic component 50 may be reduced and/or eliminated. In some embodiments, the cooperation of carrier 60 and caddy 70 may allow selection of a resonant frequency for the assembly. Selection of a resonant or natural frequency avoids a resonant frequency near the operating frequency of the electronic component. For example, a SAS hard disk drive operates at approximately 10,000 RPM with a frequency of 166 Hz. As another example, a SATA hard disk drive operates at approximately 7,000 RPM with a frequency of 120 Hz.

In some embodiments, mass 62 is chosen according to the following equation:

$$Mass \geq \frac{k}{{π}^{2} {f}^{2}}$$

“Mass” represents the sum of the mass of electronic component 50 and carrier 60. “k” represents the spring constant resulting from the structure or mounting of caddy 70. “f” represents the operating frequency of electronic component 50. When mass 62 is chosen to exceed the value for “Mass” resulting from this equation, carrier 60 and caddy 70 may cooperate to damp vibration associated with the operation of electronic component 50.

In one embodiment, carrier 60 carries a 2.5-inch hard disk drive. In that example, caddy 70 mounts carrier 60 to a 3.5-inch bay associated with an information handling system. Caddy 70 and carrier 60 may cooperate to damp enough vibration to eliminate and/or reduce the need for sound absorbing material (e.g., foam and/or padding).

The mass of caddy 70 and carrier 60 may be tuned for damping according to the above equation. In one embodiment, low frequency vibration (e.g., 120-166 Hz) of a hard disk drive may be more effectively damped by using the teachings of the present disclosure than by including foam and/or damping material previously used in the art.

A typical cooling system associated with an information handling system may be sufficient to cool a single 3.5-inch hard disk drive but may require increased fan size and/or speed to cool two 3.5-inch hard disk drives. In one embodiment of the present disclosure, carrier 60 carries two 2.5-inch hard disk drives and caddy 70 mounts carrier 60 to a 3.5-inch bay associated with an information handling system. In this embodiment, a typical cooling system associated with an information handling system may be sufficient to cool two 2.5-inch hard disk drives in conjunction with carrier 60 without increased fan size or speed.

While the present disclosure includes reference to hard disk drives, the teachings herein are applicable to any electronic component, especially those with rotating components. Although the present disclosure has been described in detail, it should be understood that various changes, substitutions, and alterations can be made hereto without departing from the spirit and the scope of the disclosure as defined by the appended claims.

What is claimed is:

1. A system for mounting an electronic component associated with an information handling system, comprising:
a carrier configured to carry an electronic component, the carrier including:
a mass providing a heat sink to the electronic component;
one or more fins for transferring heat from the mass; and
a caddy configured to mount the carrier and the electronic component to a structure of the information handling system;
wherein the carrier and the caddy operate in conjunction as a damper to attenuate vibration associated with operation of the electronic component.

2. A system according to claim 1, wherein the carrier is configured to carry a hard disk drive.

3. A system according to claim 1, further comprising a gap pad for providing thermal communication between the mass and the electronic component.

4. A system according to claim 1, further comprising a gap pad for providing thermal communication between the mass and the electronic component, the gap pad disposed on the carrier so that the gap pad will be located beneath a rotating component of the electronic component.

5. A system according to claim 1, wherein the carrier is configured to carry two hard disk drives.

6. A system according to claim 1, wherein:
the carrier is configured to carry a 2.5-inch hard disk drive; and
the caddy is configured to mount the carrier to a 3.5-inch hard disk drive bay.

7. A system according to claim 1, wherein the caddy is configured to isolate the vibration of the carrier and the electronic component from the structure of the information handling system.

8. A system according to claim 1, wherein the weight of the mass is chosen using a mathematical model to damp vibration generated by the operation of the electronic component.

9. A device associated with an information handling system, comprising:
a hard disk drive including a rotating component;
a carrier configured to carry the hard disk drive, the carrier including:
a mass providing a heat sink to the hard disk drive;
one or more fins for transferring heat from the mass; and
a caddy configured to mount the carrier and the hard disk drive to a structure of the information handling system;
wherein the carrier and the caddy operate in conjunction as a damper to attenuate vibration associated with operation of the rotating component of the hard disk drive.

10. A system according to claim 9, further comprising a gap pad for providing thermal communication between the mass and the hard disk drive, the gap pad disposed between the rotating component of the hard disk drive and the mass.

11. A system according to claim 9, wherein the carrier is configured to carry two hard disk drives.

12. A system according to claim 9, wherein:
the carrier is configured to carry a 2.5-inch hard disk drive; and
the caddy is configured to mount the carrier to a 3.5-inch hard disk drive bay.

13. A system according to claim 9, wherein the weight of the mass is chosen using a mathematical model to damp vibration generated by the operation of the electronic component.

14. An information handling system comprising:
a processor;
a memory communicatively coupled to the processor;
a frame for mounting the processor and the memory;
a carrier configured to carry an electronic component, the carrier including:
a mass providing a heat sink to the electronic component;
one or more fins for transferring heat from the mass; and
a caddy configured to mount the carrier and the electronic component to the frame;
wherein the carrier and the caddy operate in conjunction as a damper to attenuate vibration associated with operation of the electronic component.

15. A system according to claim 14, wherein the carrier is configured to carry a hard disk drive.

16. A system according to claim 14, further comprising a gap pad for providing thermal communication between the mass and the electronic component, the gap pad disposed on the carrier so that the gap pad will be located beneath a rotating component of the electronic component.

17. A system according to claim 14, wherein the carrier is configured to carry two hard disk drives.

18. A system according to claim 14, wherein:
the carrier is configured to carry a 2.5-inch hard disk drive; and
the caddy is configured to mount the carrier to a 3.5-inch hard disk drive bay.

19. A system according to claim 14, wherein the caddy is configured to isolate the carrier and the electronic component from the structure of the information handling system.

20. A system according to claim 14, wherein the weight of the mass is chosen using a mathematical model to damp vibration generated by the operation of the electronic component.
